(19) United States
(12) Patent Application Publication
(10) Pub. No.: US 2023/0197648 A1
(43) Pub. Date: Jun. 22, 2023

(54) DISPLAY PANEL AND DISPLAY APPARATUS

(71) Applicant: Wuhan China Star Optoelectronics Semiconductor Display Technology Co., Ltd., Shenzhen (CN)

(72) Inventor: Xiaobo HU, Shenzhen (CN)

(21) Appl. No.: 16/625,893

(22) PCT Filed: Nov. 25, 2019
(86) PCT No.: PCT/CN2019/120548

§ 371 Date: Dec. 23, 2019

(30) Foreign Application Priority Data
Oct. 30, 2019 (CN) 201911043628.9

(51) Int. Cl. H01L 23/00; H01L 25/16

(52) U.S. Cl. CPC H01L 24/05; H01L 25/167; H01L 24/29; H01L 24/32; H01L 24/03; H01L 2224/03622; H01L 2224/0362; H01L 2224/05557; H01L 2224/05573; H01L 2224/05611; H01L 2224/29019; H01L 2224/29109; H01L 2224/29111; H01L 2224/32145; H01L 2924/12041

(57) ABSTRACT

The present disclosure provides a display panel and a display apparatus. The display panel includes a driving back plate, a driving circuit, a first electrode layer, micro-LEDs, a second electrode layer, and a bonding layer. The first electrode layer on the driving circuit is provided with a first protruding structure, and the second electrode layer under the micro-LEDs is provided with a second protruding structure. The bonding layer is disposed between the first electrode layer and the second electrode layer to alleviate the problem of micro-LEDs falling off.

### BACKGROUND OF INVENTION

### Field of Invention

The present disclosure relates to the field of display technologies, and more particularly, to a display panel and a display apparatus.

### Description of Prior Art

Compared with current liquid crystal display (LCD) and organic light emitting diode (OLED) display devices, micro-light emitting diode (micro-LED) display devices have advantages of faster response times, wider color gamut, higher resolution, and lower energy consumption. However, they have many technical difficulties and the technologies are complicated, especially for the key technology of mass transfer technology.

Micro-LED chips need to be transferred to required positions one by one after being manufactured. A number of micro-LED chips to be transferred is large and high positional accuracy after the transfer is required, which requires consumption of a large amount of resources. With the development of technology, there have been many technical branches in the development of mass transfer technology, such as electrostatic attaching, laser bonding, etc.

Mass transfer technology is used to bond a huge number of micro-LED chips to a driving circuit of a display substrate. Tin (Sn) paste is heated to become a molten tin dot for bonding (melting point of tin is 231.89° C.). During a bonding process, micro-LEDs are not easily bonded and may fall off, which will result in dark dots of micro-LED devices.

Therefore, the problem of the existing micro-LEDs falling off need to be solved.

### SUMMARY OF INVENTION

In order to resolve the above problem, the present disclosure provides a technical solution as following. The embodiment of present disclosure provides a display panel, which includes a driving back plate, a driving circuit, a first electrode layer, micro-LEDs, a second electrode layer and a bonding layer. The driving circuit is disposed on the driving back plate. The first electrode layer is disposed on the driving circuit. The micro-LED is disposed opposite to the driving circuit. The second electrode layer is disposed under the micro-LED. The bonding layer is disposed between the first electrode layer and the second electrode layer and is used to electrically connect the driving circuit and the micro-LEDs, wherein the contact area between the bonding layer and the first electrode layer is greater than a projected area of the bonding layer orthogonally projected on the driving back plate.

In the display panel provided by the embodiment of present disclosure, a first protruding structure is disposed on the first electrode layer.

In the display panel provided by the embodiment of present disclosure, the first protruding structure has a plurality of protrusions having different heights.

In the display panel provided by the embodiment of present disclosure, a cross-sectional shape of one of the plurality of protrusions of the first protruding structure is at least one of a square, a triangle, a trapezoid, and an arc.

In the display panel provided by the embodiment of present disclosure, a contact area between the bonding layer and the second electrode layer is greater than the projected area of the bonding layer orthogonally projected on the driving back plate.

In the display panel provided by the embodiment of present disclosure, a second protruding structure is disposed on the second electrode layer.

In the display panel provided by the embodiment of present disclosure, the second protruding structure has a plurality of protrusions having different heights.

In the display panel provided by the embodiment of present disclosure, a cross-sectional shape of one of the plurality of protrusions of the second protruding structure is at least one of a square, a triangle, a trapezoid, and an arc.

In the display panel provided by the embodiment of present disclosure, the plurality of protrusions of the first protruding structure and the plurality of protrusions of the second protruding structure are oppositely disposed.

In the display panel provided by the embodiment of present disclosure, the plurality of protrusions of the first protruding structure and the plurality of protrusions of the second protruding structure are disposed in staggered arrangement.

The embodiment of present disclosure further provides a display apparatus, which includes a display panel and a display control circuit, wherein the display control circuit is used to control the display panel for screen display, the display panel includes a driving back plate, a driving circuit, a first electrode layer, micro-LEDs, a second electrode layer and a bonding layer. The driving circuit is disposed on the driving back plate. The first electrode layer is disposed on the driving circuit. The micro-LED is disposed opposite to the driving circuit. The second electrode layer is disposed under the micro-LED. The bonding layer is disposed between the first electrode layer and the second electrode layer and is used to electrically connect the driving circuit and the micro-LEDs, wherein the contact area between the bonding layer and the first electrode layer is greater than the projected area of the bonding layer orthogonally projected on the driving back plate.

In the display apparatus provided by the embodiment of present disclosure, a first protruding structure is disposed on the first electrode layer.

In the display apparatus provided by the embodiment of present disclosure, the first protruding structure has a plurality of protrusions having different heights.

In the display apparatus provided by the embodiment of present disclosure, a cross-sectional shape of one of the plurality of protrusions of the first protruding structure is at least one of a square, a triangle, a trapezoid, and an arc.

In the display apparatus provided by the embodiment of present disclosure, a contact area between the bonding layer and the second electrode layer is greater than the projected area of the bonding layer orthogonally projected on the driving back plate.

In the display apparatus provided by the embodiment of present disclosure, a second protruding structure is disposed on the second electrode layer.

In the display apparatus provided by the embodiment of present disclosure, the second protruding structure has a plurality of protrusions having different heights.

In the display apparatus provided by the embodiment of present disclosure, a cross-sectional shape of one of the plurality of protrusions of the second protruding structure is at least one of a square, a triangle, a trapezoid, and an arc.

In the display apparatus provided by the embodiment of present disclosure, the plurality of protrusions of the first protruding structure and the plurality of protrusions of the second protruding structure are oppositely disposed.

In the display apparatus provided by the embodiment of present disclosure, the plurality of protrusions of the first protruding structure and the plurality of protrusions of the second protruding structure are disposed in staggered arrangement.

The present disclosure has the following advantages. In the display panel and the display apparatus provided by the present disclosure, the contact area of the bonding layer with the first electrode layer or with the second electrode layer is increased, and the adhesion force of the bonding layer with the first electrode layer or with the second electrode layer is increased, making the micro-LED and the driving circuit more firmly bonded, and thereby solving the problem that micro-LEDs are not bonded firmly and easily fall off during the mass transfer bonding process.

### BRIEF DESCRIPTION OF DRAWINGS

In order to illustrate the technical solutions of the embodiments of the present disclosure more clearly, the following detailed description and drawings with reference to the exemplary embodiments of the present disclosure are concisely described below. Obviously, the specific embodiments described herein are only some examples of the present disclosure. Based on the following drawings, a person skilled in the art may obtain further drawings without making inventive effort.

FIG. 1 is a schematic view of a first structure of a display panel of an embodiment of the present disclosure.

FIG. 2 is a schematic view of a cross-sectional shape of a first protruding structure of an embodiment of the present disclosure.

FIGS. 3-5 are schematic views of several cross-sectional shapes of a protruding structure of an embodiment of the present disclosure.

FIG. 6 is a schematic view of a second structure of a display panel of an embodiment of the present disclosure.

FIG. 7 is a schematic view of a third structure of a display panel of an embodiment of the present disclosure.

FIGS. 8-12 are schematic views of manufactured structures in each step of a manufacturing method of a display panel of an embodiment of the present disclosure.

### DETAILED DESCRIPTION OF INVENTION

The following description of the embodiments with reference to the accompanying drawings is used to illustrate particular embodiments of the present disclosure. The directional terms referred in the present disclosure, such as “upper”, “lower”, “front”, “back”, “left”, “right”, “inner”, “outer”, “side surface”, etc. are only directions with regard to the accompanying drawings. Therefore, the directional terms used for describing and illustrating the present disclosure are not intended to limit the present disclosure. In following drawing, a same reference number denotes a same element or a similar element with same or similar structure.

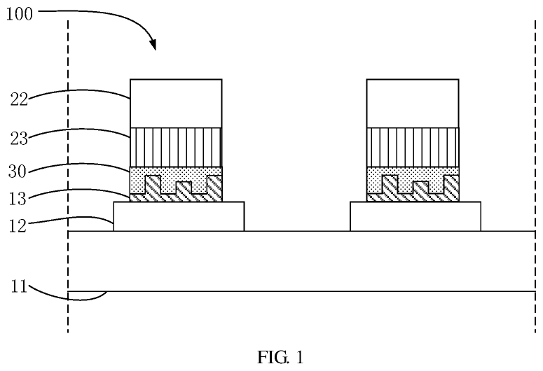

In one embodiment, as shown in FIG. 1, a display panel 100 is provided, which includes a driving back plate 11, a driving circuit 12, a first electrode layer 13, a micro-LED 22, a second electrode layer 23, and a bonding layer 30. The driving circuit 12 is disposed on the driving back plate 11. The first electrode layer 13 is disposed on the driving circuit 12. The micro-LED 22 is disposed opposite to the driving circuit 12. The second electrode layer 23 is disposed under the micro-LED 22. The bonding layer 30 is disposed between the first electrode layer 13 and the second electrode layer 23 and is used to electrically connect the driving circuit 12 and the micro-LED 22, wherein the contact area between the bonding layer 30 and the first electrode layer 13 is greater than a projected area of the bonding layer 30 orthogonally projected on the driving back plate 11.

In one embodiment, a material of the bonding layer 30 is at least one of tin, indium, and the like.

In this embodiment, by increasing the contact area between the bonding layer and the first electrode layer, the adhesion force between the bonding layer and the first electrode layer is increased, and the problem that micro-LEDs are not bonded firmly and easily fall off during the mass transfer bonding process is alleviated.

Specifically, materials of the first electrode layer 13 and the second electrode layer 23 are both conductive electrode materials. Material of the bonding layer 30 is at least one of tin, indium, and the like. The material of tin is used in this embodiment.

Specifically, the first electrode layer 13 is disposed on a surface of the driving circuit 12 and is electrically connected to the driving circuit 12. The second electrode layer 23 is disposed under the micro-LED 22 and is electrically connected to the micro-LED 22. The first electrode layer 13 and the second electrode layer 23 are bonded together by the molten tin of the bonding layer 30, so that the first electrode layer 13 and the second electrode layer 23 are electrically connected.

Further, the first electrode layer 13 and the second electrode layer 23 are electrically connected, that is, the driving circuit 12 is electrically connected to the micro-LED 22 to realize the driving circuit 12 driving the micro-LED 22.

Specifically, the micro-LED is prepared on a transfer substrate at first, and then transferred to the driving circuit through a mass transfer technology, so that the micro-LED and the driving circuit are bonded together to implement the driving circuit to drive the micro-LED, and finally the transfer substrate is stripped.

In one embodiment, a contact area between the bonding layer 30 and the first electrode layer 13 is greater than the projected area of the bonding layer 30 orthogonally projected on the driving back plate 11.

Specifically, a first protruding structure is disposed on the first electrode layer 13.

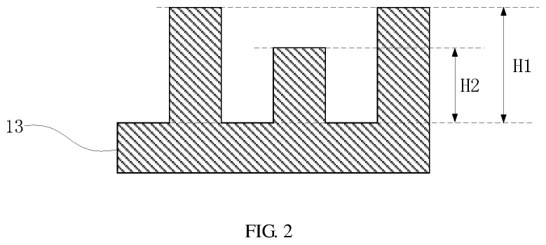

Further, the first protruding structure has a plurality of protrusions having different heights. As shown in FIG. 2, it is an enlarged view of the first electrode layer 13 illustrated in FIG. 1. As can be seen in FIG. 2, the first protruding structure on the first electrode layer 13 has a plurality of protrusions having different heights, where height H1 is greater than height H2.

Further, a cross-sectional shape of one of the plurality of protrusions of the first protruding structure is at least one of a square, a triangle, a trapezoid, or an arc. The cross-sectional shapes of the plurality of protrusions of the first protruding structure of this embodiment are all squares, as shown in FIG. 1.

Specifically, the first protruding structure is prepared on the first electrode layer 13 by a lithographic process.

Specifically, a photoresist is coated on the first electrode layer 13, and the coated photoresist is exposed through a mask to form an exposed area. The exposed area is then developed to form protruding patterns. Subsequently, the protruding patterns are dried and then etched. After the etching is completed, the photoresist on the first electrode layer 13 is peeled off to obtain the required first protruding structure.

In one embodiment, the molten tin dot of the bonding layer covers the first electrode layer, and fills grooves between a plurality of protrusions of the first protruding structure, which increases the contact area between the bonding layer and the first electrode layer.

It should be noted that the protruding shape described in the present disclosure is also a groove shape when seen from another perspective. For example, one groove is formed between every two adjacent protrusions. The application will not distinguish between protrusions and grooves, and the protrusions are taken as the example for description.

In one embodiment, a cross-sectional shape of the first protruding structure on the first electrode layer may also be at least one of a triangle, a trapezoid, or an arc.

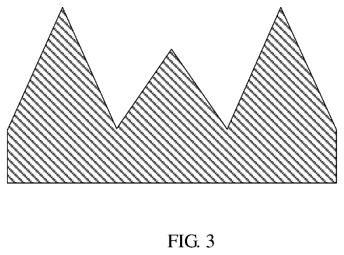

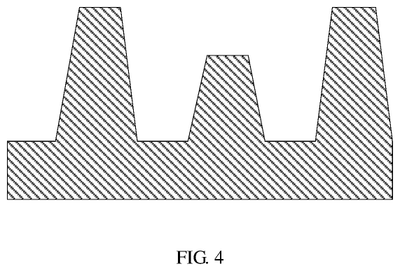

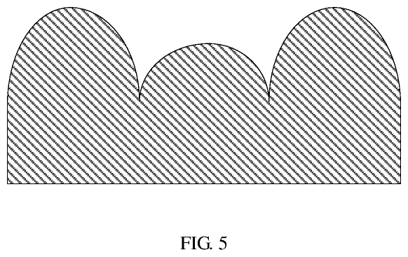

Specifically, as shown in FIG. 3, the cross-sectional shape of the first protruding structure is triangular; as shown in FIG. 4, the cross-sectional shape of the first protruding structure is trapezoidal; and as shown in FIG. 5, the cross-sectional shape of the first protruding structure is circular.

Further, the cross-sectional shape of the first protruding structure is not limited to the square, triangle, trapezoid, and arc exemplified in the present disclosure. Any shape that increases the contact area with the bonding layer by providing a protruding structure on the first electrode layer should be within the protection scope of the present application.

In this embodiment, by providing the first protruding structure on the first electrode layer, the contact area between the bonding layer and the first electrode layer is increased, thereby improving the adhesion force between the bonding layer and the first electrode layer, and alleviating the problem that the micro-LEDs are not firmly bonded and easily fall off during the mass transfer bonding process.

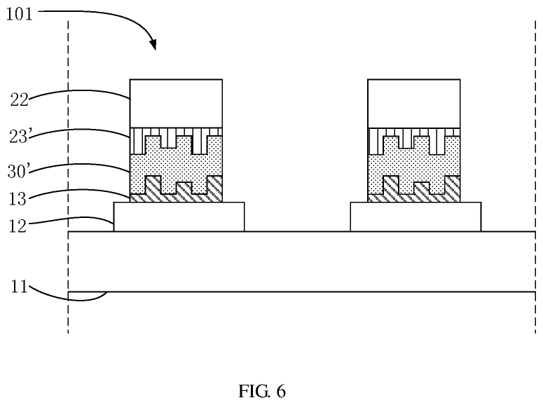

In one embodiment, as shown in FIG. 6, the display panel 101 includes a driving back plate 11, a driving circuit 12, a first electrode layer 13, a micro-LED 22, a second electrode layer 23′, and a bonding layer 30′, wherein the contact area between the bonding layer 30′ and the first electrode layer 13 is greater than the projected area of the bonding layer 30′ orthogonally projected on the driving back plate 11, and the contact area between the bonding layer 30′ and the second electrode layer 23′ is greater than the projected area of the bonding layer 30′ orthogonally projected on the driving back plate 11.

Specifically, a first protruding structure is disposed on the first electrode layer 13 and a second protruding structure is disposed on the second electrode layer 23′.

Specifically, the first protruding structure has a plurality of protrusions having different heights, as shown in FIG. 2. The second protruding structure has a plurality of protrusions having different heights, and the height difference between the plurality of protrusions of the second protruding structure is similar to that between the plurality of protrusions of the first protruding structure. Please refer to FIG. 2, as details will not be described repeatedly here.

Further, a cross-sectional shape of one of the plurality of protrusions of the first protruding structure or one of the plurality of protrusions of the second protruding structure is at least one of a square, a triangle, a trapezoid, or an arc.

Specifically, as shown in FIG. 6, the cross-sectional shapes of the plurality of protrusions of the first protruding structure and the plurality of protrusions of the second protruding structure are all squares in this embodiment.

Further, the first protruding structure and the second protruding structure are both prepared by a lithographic process.

Specifically, a photoresist is coated on the first electrode layer, and the coated photoresist is exposed through a mask to form an exposed area. The exposed area is then developed to form protruding patterns. Subsequently, the protruding patterns are dried and then etched. After the etching is completed, the photoresist on the first electrode layer is peeled off to obtain the required first protruding structure.

Further, a photoresist is coated on the second electrode layer, and the coated photoresist is exposed through a mask to form an exposed area. The exposed area is then developed to form protruding patterns. Subsequently, the protruding patterns are dried and then etched. After the etching is completed, the photoresist on the second electrode layer is peeled off to obtain the required second protruding structure.

In one embodiment, the plurality of protrusions of the first protruding structure and the plurality of protrusions of the second protruding structure are disposed in staggered arrangement, as shown in FIG. 6.

In one embodiment, the first electrode layer 13 and the second electrode layer 23′ are bonded together by the molten tin of the bonding layer 30′ to realize the electrical connection of the first electrode layer 13 and the second electrode layer 23′.

Specifically, the molten tin dot is covered on the first electrode layer prepared with the first protruding structure. The micro-LED prepared with the second protruding structure is transferred to the first electrode layer covered with the molten tin dot. The second electrode layer under the micro-LED is in contact with the molten tin dot, thus the first electrode layer is electrically connected with the second electrode layer.

Further, the first electrode layer is disposed on a surface of the driving circuit, and is electrically connected to the driving circuit. The second electrode layer is disposed under the micro-LED and is electrically connected to the micro-LED. The first electrode layer and the second electrode layer are electrically connected through the bonding layer. That is, the micro-LED is bonded to the driving circuit. At the same time, the contact area between the first electrode layer and the second electrode layer with the bonding layer is increased, the adhesion force is increased, and the micro-LED and the driving circuit are more firmly bonded and do not easily fall off.

In this embodiment, the first protruding structure and the second protruding structure are respectively provided on the first electrode layer and the second electrode layer, and the staggered arrangement of the plurality of protrusions of the first protruding structure and the plurality of protrusions of the second protruding structure are provided, which increases the contact area of the first electrode layer and the second electrode layer with the bonding layer, and increases the adhesion force, making the micro-LED and the driving circuit more firmly bonded. Compared with the previous embodiment, in which only the first protruding structure is provided on the first electrode layer, this embodiment brings better bonding effect.

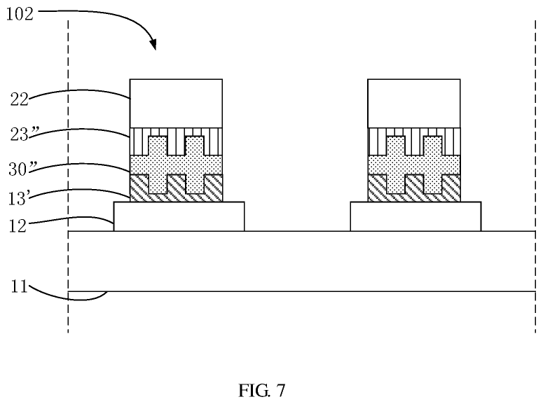

In an embodiment, different from the above embodiment, the plurality of protrusions of the first protruding structure and the plurality of protrusions of the second protruding structure are oppositely disposed, and the plurality of protrusions of the first protruding structure have the same height, and the plurality of protrusions of the second protruding structure have the same height, as shown in the display panel 102 shown in FIG. 7.

Specifically, a first protruding structure is provided on the first electrode layer 13′, and a second protruding structure is provided on the second electrode layer 23″. The bonding layer 30″ is located between the first electrode layer 13′ and the second electrode layer 23″, such that the first electrode layer 13′ and the second electrode layer 23″ are electrically connected. For other descriptions, please refer to the above embodiments, as such descriptions will not be described repeatedly here.

In one embodiment, the second protruding structure is provided on the second electrode layer, but the first protruding structure is not provided on the first electrode layer; the electrical connection between the micro-LED and the driving circuit can still be achieved, and the micro-LED and the driving circuit are more firmly bonded. For specific implementation, please refer to the description of the foregoing embodiments, and it will not be described repeatedly here.

It should be noted that the number of protrusions of the first protruding structure or the second protruding structure in the present application may be set to one or more according to an actual manufacturing process. The plurality of protrusions of the first protruding structure or the plurality of protrusions of the second protruding structure in the illustrations of the foregoing embodiments are described by taking three protrusions as an example, but the present application should not be limited to this. In addition, the cross-sectional shape of the plurality of protrusions of the first protruding structure or the plurality of protrusions of the second protruding structure may not be limited to one kind, and may be a combination of a plurality of kinds. The above embodiments are described by using the same cross-sectional shape of the plurality of protrusions in the same protruding structure as an example.

In one embodiment, a method for preparing the above-mentioned display panel is provided. Taking the display panel shown in FIG. 7 as an example, the method includes the following steps:

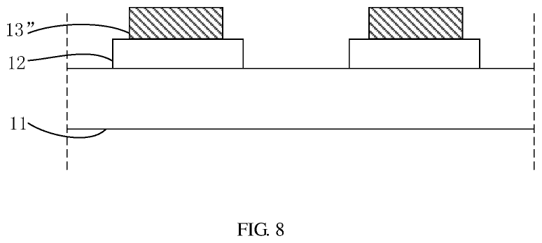

step S1: providing a driving substrate, including a driving back plate 11, a driving circuit 12, and a first electrode layer 13″, as shown in FIG. 8;

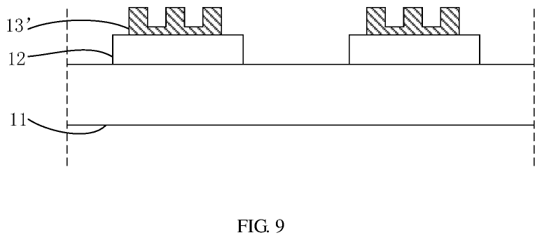

step S2: a step of preparing a first protruding structure, including preparing a first protruding structure on the first electrode layer 13′ by using a lithographic process, the first electrode layer 13′ prepared with the first protruding structure is as shown in FIG. 9;

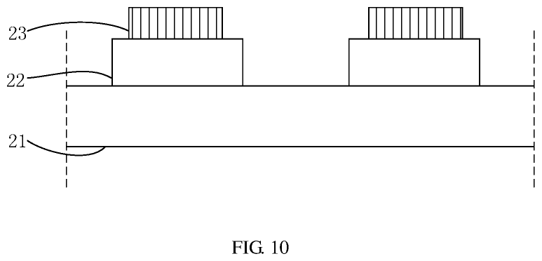

step S3: providing a completed micro-LED array transfer substrate, including a substrate 21, a micro-LED 22, and a second electrode layer 23, as shown in FIG. 10;

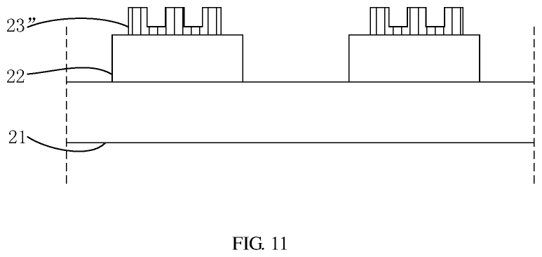

step S4: a step of preparing a second protruding structure, which includes preparing a second protruding structure on the second electrode layer 23″ by using a lithographic process, the second electrode layer 23″ prepared with the second protruding structure is as shown in FIG. 11;

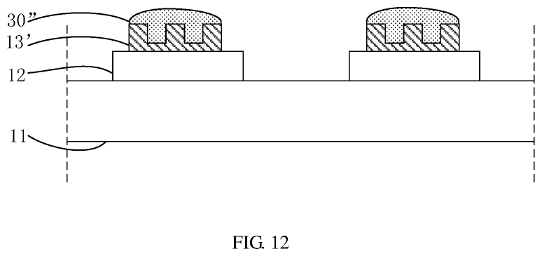

step S5: a step of preparing a bonding layer, comprising covering the first electrode layer 13′ prepared with the first protruding structure with molten tin dots 30″, as shown in FIG. 12;

step S6: the micro-LED transfer step, including transferring the micro-LEDs on the transfer substrate to the first electrode layer covered with the molten tin dots for bonding them together, and peeling off the substrate on the transfer substrate to form the display panel as shown in FIG. 7.

Specifically, in step S1, the driving circuit is disposed on the driving back plate, and the first electrode layer is disposed on the driving circuit.

Specifically, in step S2, a photoresist is coated on the first electrode layer, and the coated photoresist is exposed through a mask to form an exposed area. The exposed area is then developed to form protruding patterns. Subsequently, the protruding patterns are dried and then etched. After the etching is completed, the photoresist on the first electrode layer is peeled off to obtain the required first protruding structure.

Specifically, in step S3, the micro-LED is disposed on the substrate, and the second electrode layer is disposed under the micro-LED.

Specifically, in step S4, a photoresist is coated on the second electrode layer, and the coated photoresist is exposed through a mask to form an exposed area. The exposed area is then developed to form protruding patterns. Subsequently, the protruding patterns are dried and then etched. After the etching is completed, the photoresist on the second electrode layer is peeled off to obtain the required second protruding structure.

Specifically, in step S6, the micro-LEDs prepared with the second protruding structure are transferred to the first electrode layer covered with the molten tin dots, and the second electrode layer is brought into contact with the molten tin dots to electrically connect the first electrode layer and the second electrode layer.

Further, the first electrode layer is disposed on a surface of the driving circuit, and is electrically connected to the driving circuit. The second electrode layer is disposed under the micro-LED and is electrically connected to the micro-LED. The first electrode layer and the second electrode layer are electrically connected through the bonding layer. That is, the micro-LED is bonded to the driving circuit. At the same time, the contact area between the first electrode layer and the second electrode layer with the bonding layer is increased, the adhesion force is increased, and the micro-LED and the driving circuit are more firmly bonded and do not easily fall off.

In one embodiment, a display device is provided, which includes a display panel and a display control circuit, wherein the display control circuit is used to control the display panel for screen display, and the display panel includes a driving back plate, a driving circuit, a first electrode layer, micro-LEDs, a second electrode layer, and a bonding layer. The driving circuit is disposed on the driving back plate. The first electrode layer is disposed on the driving circuit. The micro-LED is disposed opposite to the driving circuit. The second electrode layer is disposed under the micro-LED. The bonding layer is disposed between the first electrode layer and the second electrode layer, and is used to electrically connect the driving circuit and the micro-LED, wherein the contact area between the bonding layer and the first electrode layer is greater than the projected area of the bonding layer orthogonally projected on the driving back plate.

In one embodiment, a first protruding structure is provided on the first electrode layer.

Specifically, the first protruding structure has a plurality of protrusions having different heights.

Specifically, a cross-sectional shape of one of the plurality of protrusions of the first protruding structure is at least one of a square, a triangle, a trapezoid, or an arc.

In one embodiment, the contact area between the bonding layer and the second electrode layer is greater than the projected area of the bonding layer orthogonally projected on the driving back plate.

Specifically, a second protruding structure is provided on the second electrode layer.

Specifically, the second protruding structure has a plurality of protrusions having different heights.

Specifically, a cross-sectional shape of one of the plurality of protrusions of the second protruding structure is at least one of a square, a triangle, a trapezoid, or an arc.

In one embodiment, the plurality of protrusions of the first protruding structure and the plurality of protrusions of the second protruding structure are oppositely disposed.

In one embodiment, the plurality of protrusions of the first protruding structure and the plurality of protrusions of the second protruding structure are disposed in staggered arrangement.

According to above embodiments, the present disclosure provides a display panel, a manufacturing method of the same, and a display apparatus. The display panel includes a driving back plate, a driving circuit, a first electrode layer, micro-LEDs, a second electrode layer, and a bonding layer. The driving circuit is disposed on the driving back plate and is disposed opposite to the micro-LED, wherein the first electrode layer on the driving circuit is provided with a first protruding structure, and the second electrode layer under the micro-LED is provided with a second protruding structure. The bonding layer is disposed between the first electrode layer and the second electrode layer, to electrically connect the driving circuit and the micro-LED. By providing protrusions on the first electrode layer and the second electrode layer, the contact area of the bonding layer with the first electrode layer or with the second electrode layer is increased, and the adhesion force of the bonding layer with the first electrode layer or with the second electrode layer is increased, making the micro-LED and the driving circuit more firmly bonded, and thereby alleviating the problem that micro-LEDs are not bonded firmly and easily fall off during the mass transfer bonding process.

The specific embodiments described herein are only for explaining the present disclosure. It should be noted that various changes and modifications can be made to the invention in light of the above detailed description by those skilled in the art, and those various changes and modifications should be considered to be pertained to the scope of the present invention.

What is claimed is:

1. A display panel, comprising:
a driving back plate;
a driving circuit disposed on the driving back plate;
a first electrode layer disposed on the driving circuit;
at least one micro-LED disposed opposite to the driving circuit;
a second electrode layer disposed under the at least one micro-LED; and
a bonding layer disposed between the first electrode layer and the second electrode layer to electrically connect the driving circuit and the at least one micro-LED;
wherein a contact area between the bonding layer and the first electrode layer is greater than a projected area of the bonding layer orthogonally projected on the driving back plate.

2. The display panel according to claim 1, wherein a first protruding structure is disposed on the first electrode layer.

3. The display panel according to claim 2, wherein the first protruding structure has a plurality of protrusions having different heights.

4. The display panel according to claim 3, wherein a cross-sectional shape of one of the plurality of protrusions of the first protruding structure is at least one of a square, a triangle, a trapezoid, or an arc.

5. The display panel according to claim 3, wherein a contact area between the bonding layer and the second electrode layer is greater than the projected area of the bonding layer orthogonally projected on the driving back plate.

6. The display panel according to claim 5, wherein a second protruding structure is disposed on the second electrode layer.

7. The display panel according to claim 6, wherein the second protruding structure has a plurality of protrusions having different heights.

8. The display panel according to claim 7, wherein a cross-sectional shape of one of the plurality of protrusions of the second protruding structure is at least one of a square, a triangle, a trapezoid, or an arc.

9. The display panel according to claim 8, wherein the plurality of protrusions of the first protruding structure and the plurality of protrusions of the second protruding structure are oppositely disposed.

10. The display panel according to claim 8, wherein the plurality of protrusions of the first protruding structure and the plurality of protrusions of the second protruding structure are disposed in staggered arrangement.

11. A display apparatus having a display panel and a display control circuit, wherein the display control circuit is used to control the display panel for screen display, the display panel comprising:
a driving back plate;
a driving circuit disposed on the driving back plate;
a first electrode layer disposed on the driving circuit;
at least one micro-LED disposed opposite to the driving circuit;
a second electrode layer disposed under the at least one micro-LED; and
a bonding layer disposed between the first electrode layer and the second electrode layer to electrically connect the driving circuit and the at least one micro-LED;
wherein a contact area between the bonding layer and the first electrode layer is greater than a projected area of the bonding layer orthogonally projected on the driving back plate.

12. The display apparatus according to claim 11, wherein a first protruding structure is disposed on the first electrode layer.

13. The display apparatus according to claim 12, wherein the first protruding structure has a plurality of protrusions having different heights.

14. The display apparatus according to claim 13, wherein a cross-sectional shape of one of the plurality of protrusions of the first protruding structure is at least one of a square, a triangle, a trapezoid, or an arc.

15. The display apparatus according to claim 13, wherein a contact area between the bonding layer and the second electrode layer is greater than the projected area of the bonding layer orthogonally projected on the driving back plate.

16. The display apparatus according to claim 15, wherein a second protruding structure is disposed on the second electrode layer.

17. The display apparatus according to claim 16, wherein the second protruding structure has a plurality of protrusions having different heights.

18. The display apparatus according to claim 17, wherein a cross-sectional shape of one of the plurality of protrusions of the second protruding structure is at least one of a square, a triangle, a trapezoid, or an arc.

19. The display apparatus according to claim 18, wherein the plurality of protrusions of the first protruding structure and the plurality of protrusions of the second protruding structure are oppositely disposed.

20. The display apparatus according to claim 18, wherein the plurality of protrusions of the first protruding structure and the plurality of protrusions of the second protruding structure are disposed in staggered arrangement.
